(19) United States
(12) Patent Application Publication
(10) Pub. No.: US 2025/0163562 A1
(43) Pub. Date: May 22, 2025

(54) SHADOW EVAPORATION MASK FOR FABRICATING TUNNEL JUNCTION DEVICES

(71) Applicant: International Business Machines Corporation, Armonk, NY (US)

(72) Inventors: Marco Turchetti, White Plains, NY (US); Santino Carnevale, Stamford, CT (US)

(21) Appl. No.: 18/517,428

(22) Filed: Nov. 22, 2023

(51) Int. Cl. C23C 14/04; C23C 14/24; H10N 60/01; H10N 60/12

(52) U.S. Cl. CPC C23C 14/042; C23C 14/24; H10N 60/0912; H10N 60/12

(57) ABSTRACT

A method comprises forming a shadow evaporation mask on a substrate, and utilizing the shadow evaporation mask to perform a double angle evaporation process to form a plurality of tunnel junction devices in each of the different regions of the substrate. The shadow evaporation mask comprises a plurality of patterned openings in different regions of the substrate, wherein each of the patterned openings comprises a same size and shaped opening. The tunnel junction devices each comprise a first metal layer and a second metal layer having an overlapping area, wherein the overlapping areas of the tunnel junction devices are invariant over the different regions of the substrate.

### BACKGROUND

This disclosure generally relates to techniques for shadow evaporation fabrication of superconducting tunnel junction devices (e.g., Josephson junction devices) and, in particular, evaporation mask designs for shadow evaporation fabrication of superconducting tunnel junction devices, such as Josephson junctions of superconducting quantum components. A quantum computing system can be implemented using superconducting circuits and devices that utilize superconducting quantum bits for generating and processing quantum information. In general, superconducting quantum bits (qubits) are electronic circuits which are implemented using components such as superconducting tunnel junction devices (e.g., Josephson junctions), inductors, and/or capacitors, etc., and which behave as quantum mechanical anharmonic (non-linear) oscillators with quantized states, when cooled to cryogenic temperatures.

Continuing technological advances in quantum processor design are enabling the rapid scaling of both the physical number of superconducting qubits and the computational capabilities of quantum processors. Indeed, while current state-of-the art quantum processors have greater than 50 qubits, it is anticipated that future quantum processors will have a much larger number of qubits, e.g., on the order of hundreds or thousands of qubits, or more. As quantum processors are scaled, fabrication techniques should be implemented to ensure uniformity and reliability of quantum components that are fabricated over a large wafer area. For example, since Josephson junctions are core elements of quantum bits and other quantum components of superconducting quantum computers, it is desirable to implement a wafer-scale process that enables precise control of junction sizes of Josephson junctions that formed over the wafer area.

Currently, superconducting tunnel junction devices, such as Josephson junctions, are fabricated using scanning electron-beam lithography and double-angle shadow evaporation techniques which utilize shadow evaporation masks to fabricate overlapping electrodes of tunnel junction devices, with an intermediate in-situ oxidation to form a junction barrier between the overlapping electrodes. The primary variables that affect Josephson coupling energy of Josephson junctions are the overlap area between the two junction electrodes and the thickness of the tunnel barrier layer therebetween.

When performing double-angle electron-beam evaporation of Josephson junctions, diverging evaporated metal flows are formed which have conical shapes. For wafer-scale manufacturing of Josephson junctions over a large wafer area, the conical shapes of the evaporated metal flows can lead to nanoscale misalignments of the shadow images of the positions of the junction electrodes that are formed by use of the shadow evaporation mask, as well as linear dimensions of the junction electrodes. Indeed, the conical shapes of the evaporated metal flows effectively result in variations of the deposition angles of the evaporated metal over the wafer area, from the center point of the wafer to the edges of the wafer. As a result, wafer-scale manufacturing of tunnel junction devices, such as superconducting Josephson junctions, using double-angle electron-beam evaporation techniques can lead to significant variation and non-uniformities in the sizes of the tunnel junction devices (e.g., different overlap areas) over a large wafer area, which is undesirable.

### SUMMARY

Exemplary embodiments of the disclosure include techniques for shadow evaporation fabrication of tunnel junction devices (e.g., superconducting tunnel junction devices such as Josephson junction devices) and, in particular, shadow evaporation masks for double shadow evaporation fabrication of tunnel junction devices, which are designed to enable wafer-scale fabrication of tunnel junction devices having uniform sizes over a given wafer area.

For example, an exemplary embodiment includes a method which comprises forming a shadow evaporation mask on a substrate, and utilizing the shadow evaporation mask to perform a double angle evaporation process to form a plurality of tunnel junction devices in each of the different regions of the substrate. The shadow evaporation mask comprises a plurality of patterned openings in different regions of the substrate, wherein each of the patterned openings comprises a same size and shaped opening. The tunnel junction devices each comprise a first metal layer and a second metal layer having an overlapping area, wherein the overlapping areas of the tunnel junction devices are invariant over the different regions of the substrate.

Advantageously, an exemplary shadow evaporation mask is designed to have patterned openings of the same size and configuration to enable double-angle evaporation of junction electrodes of tunnel junction devices over a large substrate area where the tunnel junction devices are fabricated with uniform area over the substate area despite changes in the deposition angles based on the different positions of the tunnel junction devices over the area of the substrate.

For example, in another exemplary embodiment, as may be combined with the preceding paragraphs, the patterned openings of the shadow evaporation mask are configured to provide self-correction of geometric errors in the forming of the first and second metal layers of the tunnel junction devices in the different regions of the substrate to achieve an invariant amount of overlap area between the first metal layer and the second metal layer of each of the tunnel junction devices over the different regions of the substrate.

In another exemplary embodiment, as may be combined with the preceding paragraphs, performing the double angle evaporation process comprises: performing a first evaporation process at a first angle to deposit the first metal layer of each tunnel junction device, wherein the first metal layer of each tunnel junction device comprises a first shadow image of a respective one of the patterned openings; forming an insulating layer on the first metal layer of each tunnel junction device; and performing a second evaporation process at a second angle to deposit the second metal layer of each tunnel junction device, wherein the second metal layer of each tunnel junction device comprises a second shadow image of the respective one of the patterned openings.

In another exemplary embodiment, as may be combined with the preceding paragraphs, the patterned openings of the shadow evaporation mask each comprise a same size and quadrilateral-shaped opening with at least one non-right angle.

Another exemplary embodiment includes a method which comprises: forming a shadow evaporation mask on a substrate, the shadow evaporation mask comprising a plurality of patterned openings in different regions of the substrate, wherein each of the patterned openings comprises a same size and quadrilateral-shaped opening with at least one non-right angle; performing a first evaporation process at a first angle to deposit first metal layers which comprise first shadow images of the patterned openings; forming an insulating layer on each of the first metal layers; and performing a second evaporation process at a second angle to deposit second metal layers which comprise second shadow images of the patterned openings. Portions of the second metal layers overlap respective portions of the first metal layers to form respective tunnel junction devices in the different regions of the substrate, which comprises overlapping regions of metallization having a same size and quadrilateral-shaped footprint with at least one non-right angle.

Another exemplary embodiment includes a device which comprises a shadow evaporation mask comprising a first layer and a second layer disposed over the first layer, and plurality of uniformly patterned openings that are configured for fabricating respective uniformly shaped tunnel junction devices on a substrate by double-angle shadow evaporation.

Another exemplary embodiment includes a device which comprises a first metal layer disposed on a substrate; an insulating layer disposed on the first metal layer; and a second metal layer disposed on the insulating layer. A portion of the second metal layer overlaps a portion of the first metal layer to form a stacked structure comprising an overlapping area of metallization with a portion of the insulating layer disposed therebetween, wherein the stacked structure comprises a tunnel junction device having a quadrilateral-shaped footprint with a least one non-right angle.

In another exemplary embodiment, as may be combined with the preceding paragraphs, the first metal layer and the second metal layer each comprise a superconducting metal, and the insulating layer comprises an oxide of the superconducting metal.

In another exemplary embodiment, as may be combined with the preceding paragraphs, the quadrilateral-shaped footprint of the tunnel junction device comprises a parallelogram-shaped footprint with non-right angles. The first metal layer and the second metal layer each comprise a parallelogram-shaped area with non-right angles.

In another exemplary embodiment, as may be combined with the preceding paragraphs, the first metal layer comprises an extended portion which provides a first contact pad for the tunnel junction device, and the second metal layer comprises an extended portion which provides a second contact pad for the tunnel junction device.

In another exemplary embodiment, as may be combined with the preceding paragraphs, the tunnel junction device comprises a Josephson junction of a superconducting quantum bit.

Another exemplary embodiment includes a device which comprises a plurality of tunnel junction devices disposed on a substrate. Each tunnel junction device comprises a respective stacked structure which comprises overlapping portions of a first metal layer and a second metal layer, and an insulating layer disposed therebetween, wherein the respective stacked structure comprises a quadrilateral-shaped footprint with a least one non-right angle.

In another exemplary embodiment, as may be combined with the preceding paragraphs, wherein the quadrilateral-shaped footprints of the stacked structures have substantially a same footprint area.

Other embodiments of the disclosure will be described in the following detailed description of embodiments, which is to be read in conjunction with the accompanying figures.

### BRIEF DESCRIPTION OF THE DRAWINGS

FIGS. 1A, 1B, and 1C schematically illustrate a shadow evaporation mask formed on a substrate, according to an exemplary embodiment of the disclosure, wherein FIG. 1A is a schematic top plan view of the shadow evaporation mask and substrate, FIG. 1B is a schematic cross-sectional side view of the shadow evaporation mask and substrate along line 1B-1B in FIG. 1A, and FIG. 1C is schematic cross-sectional side view of the shadow evaporation mask and substrate along line 1C-1C in FIG. 1A.

FIGS. 2A, 2B, and 2C schematically illustrate a double-angle shadow evaporation process for wafer scale fabrication of tunnel junction devices, according to an exemplary embodiment of the disclosure.

FIGS. 3A, 3B, 3C, 3D, 3E, 3F, 3G, and 3H schematically illustrate a double-angle shadow evaporation process for wafer scale fabrication of tunnel junction devices, according to an exemplary embodiment of the disclosure.

FIGS. 4A and 4B schematically illustrate a method by which a shadow evaporation mask is configured to compensate for a first component of error in a wafer-scale fabrication of metal electrodes of tunnel junction devices using a double-angle shadow evaporation process, according to an exemplary embodiment of the disclosure.

FIG. 5 schematically illustrates a method for determining an amount of lateral overlap of metal electrodes of a tunnel junction device that is fabricated using a double-angle shadow evaporation process, according to an exemplary embodiment of the disclosure.

FIG. 6 schematically illustrates exemplary configuration of a double-angle shadow evaporation process for wafer-scale fabrication of tunnel junction devices to achieve a same amount of lateral overlap of metal electrodes of respective tunnel junction devices formed in different areas of the wafer, according to an exemplary embodiment of the disclosure.

FIGS. 7A and 7B schematically illustrate a double-angle shadow evaporation process for wafer-scale fabrication of tunnel junction devices, according to another exemplary embodiment of the disclosure.

### DETAILED DESCRIPTION

Exemplary embodiments of the disclosure will now be discussed in further detail with regard to techniques for shadow evaporation fabrication of superconducting tunnel junction devices (e.g., Josephson junction devices) and, in particular, shadow evaporation masks for double shadow evaporation fabrication of superconducting tunnel junction devices, which are designed to enable fabrication of superconducting tunnel junction devices having uniform sizes over a large wafer area. In particular, the evaporation masks are designed for use in performing a double angle evaporation process to form a plurality of superconducting tunnel junctions in different regions of the wafer, wherein the superconducting tunnel junction devices comprise respective first and second metal layers having an overlapping area that is substantially invariant over the wafer. As explained in further detail below, the exemplary shadow evaporation masks are designed to provide self-correction of a process variation due to the changing deposition angle over the wafer (from the center point of the wafer to edges), which would otherwise result in a different shading of a metal flow from a two-layer resist mask edge, to thereby provide unform area of, e.g., Josephson junctions over a wafer substrate, for large scale manufacturing.

It is to be understood that the various layers, structures, and regions shown in the accompanying drawings are schematic illustrations that are not drawn to scale. In addition, for ease of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the drawings to denote the same or similar features, elements, or structures, and thus, a detailed explanation of the same or similar features, elements, or structures will not be repeated for each of the drawings. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount. The term “exemplary” as used herein means “serving as an example, instance, or illustration”. Any embodiment or design described herein as “exemplary” is not to be construed as preferred or advantageous over other embodiments or designs. The word “over” as used herein to describe forming a feature (e.g., a layer) “over” a side or surface, means that the feature (e.g., the layer) may be formed “directly on” (i.e., in direct contact with) the implied side or surface, or that the feature (e.g., the layer) may be formed “indirectly on” the implied side or surface with one or more additional layers disposed between the feature (e.g., the layer) and the implied side or surface.

Further, the term “quantum chip” as used herein is meant to broadly refer to any device which comprises qubits and possibly other quantum devices. For example, a quantum chip can be semiconductor die which comprises an array (lattice) of qubits, which is fabricated on a wafer comprising multiple dies, and which can be diced (cut) from the wafer using a die singulation process to provide a singulated die. In some instances, a quantum chip can be a wafer with multiple quantum die. In the context of quantum computing, a quantum chip may comprise one or more processors for a quantum computer.

To provide spatial context to the different structural orientations of the semiconductor structures shown in the drawings, XYZ Cartesian coordinates are shown in the drawings. The terms “vertical” or “vertical direction” or “vertical height” as used herein denote a Z-direction of the Cartesian coordinates shown in the drawings, and the terms “horizontal,” “horizontal direction,” “lateral,” or “lateral direction” as used herein denote an X-direction and/or a Y-direction of the Cartesian coordinates shown in the drawings.

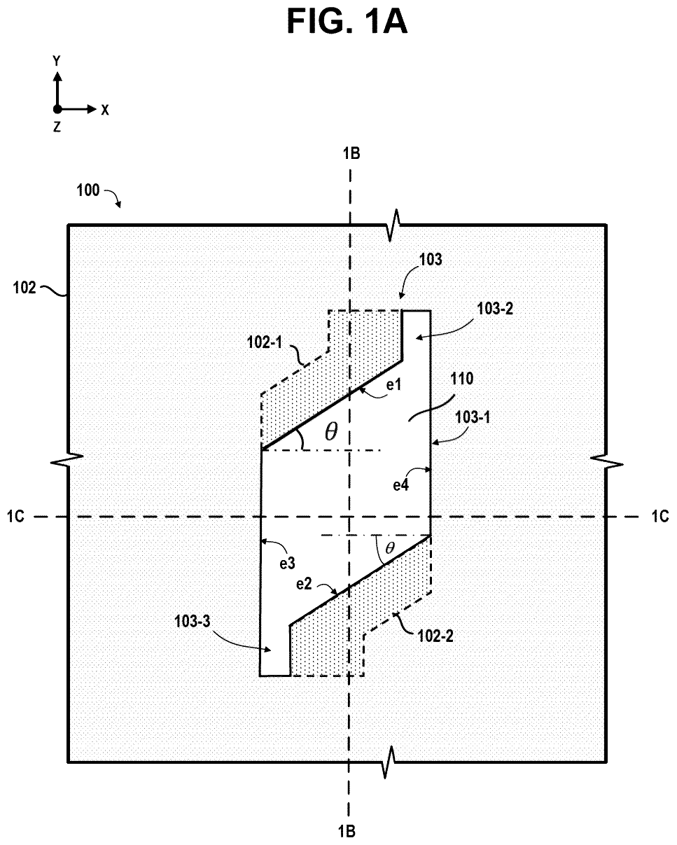

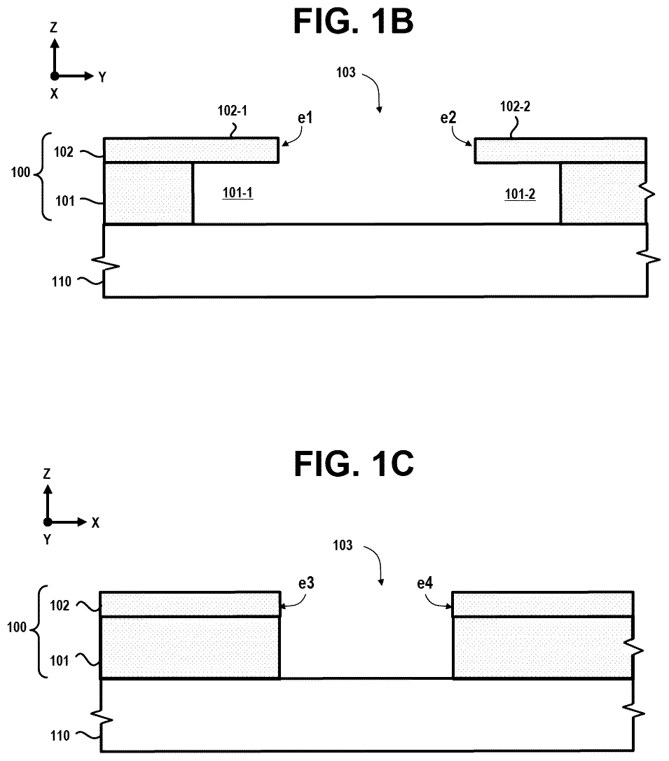

FIGS. 1A, 1B, and 1C schematically illustrate a shadow evaporation mask, according to an exemplary embodiment of the disclosure. In particular, FIGS. 1A, 1B, and 1C schematically illustrate a shadow evaporation mask 100 that is formed on a surface of a substrate 110 (e.g., wafer), wherein FIG. 1A is a schematic top plan view of the shadow evaporation mask 100, FIG. 1B is a schematic cross-sectional side view of the shadow evaporation mask 100 and the substrate 110 along line 1B-1B in FIG. 1A, and FIG. 1C is schematic cross-sectional side view of the shadow evaporation mask 100 and the substrate 110 along line 1C-1C in FIG. 1A.

As collectively shown in FIGS. 1A, 1B, and 1C, the shadow evaporation mask 100 comprises a first resist layer 101 (or supporting layer) and a second resist layer 102 (or imaging layer), which are etched to form a patterned opening 103 to expose a region of the underlying substrate 110 where a superconducting tunnel junction device is to be fabricated. In general, the patterned opening 103 of the second resist layer 102 comprises a quadrilateral-shaped opening 103-1 (with at least one non-right angle) which is defined by a first edge e1, a second edge e2, a third edge e3, and a fourth edge e4. In addition, the patterned opening 103 in the second resist layer 102 comprises rectangular-shaped extended portions 103-2 and 103-3. In an exemplary embodiment, the quadrilateral-shaped opening 103-1 comprises a parallelogram-shaped opening (with non-right angles). As explained below, the quadrilateral-shaped opening 103-1 (with at least one non-right angle) is configured to generate images of a first device electrode and a second device electrode with a well-defined overlapping region that forms a given superconducting tunnel junction device, and the rectangular-shaped extended portions 103-2 and 103-3 are configured to generate images of first contact pad for the first device electrode, and a second contact pad of the second device electrode of the given superconducting tunnel junction device. For purposes of discussion, exemplary embodiment of the disclosure will be discussed in the context of the quadrilateral-shaped opening 103-1 being a parallelogram-shaped opening with non-right angles, although other types of quadrilateral-shaped openings with non-right angles may be implemented.

As further schematically shown in FIGS. 1A and 1B, the second resist layer 102 of the shadow evaporation mask 100 comprises overhang portions 102-1 and 102-2 (or suspended portions) that are disposed over respective undercut regions 101-1 and 101-2 of the first resist layer 101. In this regard, the patterned opening 103 is further defined by the undercut regions 101-1 and 101-2 of the first resist layer 101. As explained in further detail below, the undercut regions 101-1 and 101-2 of the first resist layer 101 facilitate the formation of shadow images of the patterned opening 103 to be projected onto the same region of the substrate 110 (but with a given lateral offset) by performing two evaporation deposition steps at different angles to create an overlay of two metal layers with a well-defined geometry that defines a superconducting tunnel junction device.

Referring to FIG. 1A, the parallelogram-shaped opening 103-1 in the second resist layer 102 comprises a first angled edge and a second angled edge, which are defined at least in part by the first edge e1 and the second edge e2. The first angled edge and the second angled edge are each disposed at an angle θ relative to a first central axis of the substrate 110 (e.g., X-direction). As explained in further detail below, the angle θ is designed to be greater than a maximum evaporation angle θₘₐₓ of a conical-shaped evaporation metal flow generated by an evaporation source when performing a first evaporation process and a second evaporation process, wherein θ>θₘₐₓ is an exemplary design parameter that enables uniform fabrication of superconducting tunnel junction devices in different regions of the substrate (e.g., wafer) irrespective of position of superconducting tunnel junction device over the substrate.

It is to be understood that FIGS. 1A, 1B, and 1C depict only one patterned opening 103 in given region of the shadow evaporation mask 100, for purposes of ease of illustration and explanation. However, it is to be understood that in some embodiments, the shadow evaporation mask 100 would be fabricated to have multiple instances of the same patterned opening 103 (e.g., same size and geometric configuration, and orientation) in different regions of the shadow evaporation mask 100 to enable double-angle shadow evaporation fabrication of multiple superconducting tunnel junction devices in different regions of the substrate 110 having the same overlapping area of first and second metal electrodes using the same size patterned opening 103 over a large area of the substrate 110.

The shadow evaporation mask 100 can be fabricated using suitable techniques and materials. For example, in some embodiments, the shadow evaporation mask 100 comprises a bilayer resist stack that is formed by depositing a first layer of resist material (which comprises the first resist layer 101) on the substrate 110, and depositing a second layer of resist material (which comprises the second resist layer 102) on the first layer of resist material. In some embodiments, the first resist layer 101 comprises a layer of methyl methacrylate (MMA) that is spin-coated onto the surface of the substrate 110 (e.g., silicon wafer), and the second resist layer 102 comprises a layer of poly methyl methacrylate (PMMA) that is spin-coated on the first resist layer 101. In some embodiments, the first and second resist layers 101 and 102 are then patterned using scanning electron-beam lithography and suitable development solutions to form the patterned opening 103, and control the formation of the undercut regions 101-1 and 101-2 in the first resist layer 101.

For example, in some embodiments, different regions of the bilayer resist stack are exposed to different doses of electron beam energy to facilitate the formation of the patterned opening 103 that extends through both the first and second resist layers 101 and 102, and to control the formation of the undercut regions 101-1 and 101-2 in the first resist layer 101. In particular, in some embodiments, the footprint area of the bilayer resist stack corresponding to the patterned opening 103 is exposed to a “full dose” of electron beam energy which is sufficient to expose portions of both the first and second resist layers 101 and 102, so that the exposed portions can be removed using a suitable developer solution. Further, the footprint areas of the bilayer resist stack corresponding to the overhang portions 102-1 and 102-2 of the second resist layer 102 and the corresponding undercut regions 101-1 and 101-2 of the first resist layer 101 are exposed to a low dose (e.g., ghost dose) of electron beam energy which is sufficient to pass through the second resist layer 102 without affecting it, while allowing the regions of the first resist layer 101 corresponding to the undercut regions 101-1 and 101-2 to be selectively exposed, and removable by a developer solution. After the electron beam exposure, a suitable developer solution (or solutions) is then used to remove the exposed portions of the first and second resist layers 101 and 102 and thereby form the patterned opening 103 (which extends through the first and second resist layers 101 and 102 down to the surface of the substrate 110), and form the undercut regions 101-1 and 101-2 in the first resist layer 101, resulting in the exemplary patterned opening 103 shown in FIGS. 1A, 1B, and 1C. With this process, the extents of the undercut regions 101-1 and 101-2 in the first resist layer 101 are defined lithographically and thus precisely controlled.

While a shadow evaporation mask 100 can be fabricated by patterning a bilayer MMA/PMMA resist using electron-beam lithography, in other embodiments, a shadow evaporation mask for wafer-scale fabrication of tunnel junction devices can be fabricated using optical lithography. Indeed, since the an exemplary mask for shadow evaporation of, e.g. Josephson junctions, is fabricated to have the same size and configuration of the patterned openings for double-angle evaporation of junction electrodes over a large wafer area, there is no need (as with some conventional methods) to computationally determine, and then fabricate different size patterned openings in the shadow evaporation mask in order to compensate for variation in evaporation angle at different positions over the large wafer area. In electron beam lithography, the different size patterned openings can be determined computationally, and then individually formed, one at a time, using electron-beam lithography. However, the combination of computational methods and electron beam-based lithography are not an ideal solution for fabrication shadow evaporation masks especially for large-scale manufacturing. On the other hand, optical lithography-based fabrication of shadow evaporation masks is more ideal for wafer-scale manufacture of, e.g., Josephson junctions, wherein computational solutions are less adequate for optical lithography-based fabrication of shadow evaporation masks.

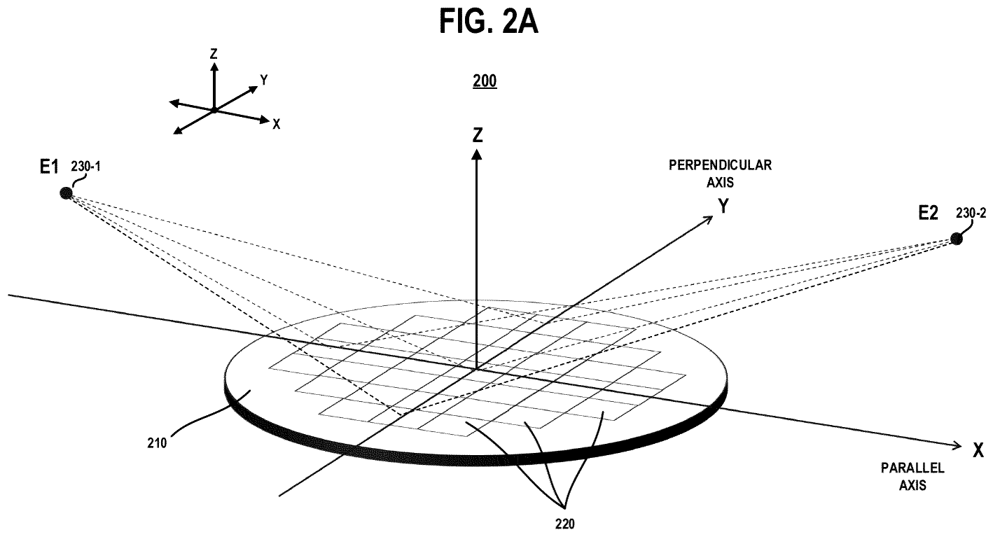

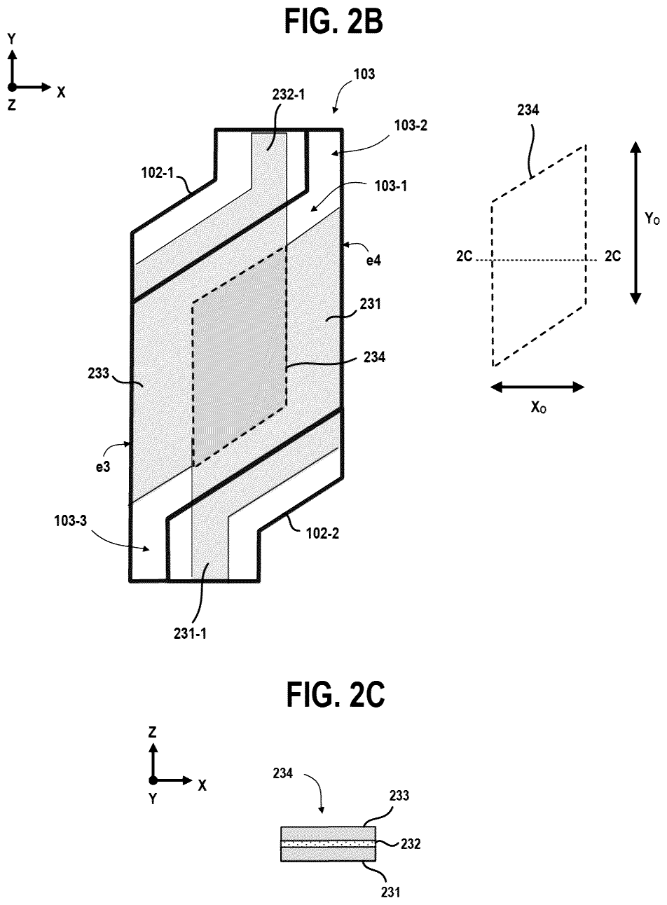

The exemplary shadow evaporation mask 100 can be utilized to perform a double-angle shadow evaporation process to fabricate first and second metallic electrodes of a given superconducting tunnel junction device which comprises shadow images of the patterned opening 103, wherein the first and second electrodes are geometrically similar, but laterally offset from each other to provide an overlapping region that defines an area of the given superconducting tunnel junction device. For example, FIGS. 2A, 2B, and 2C schematically illustrate a double-angle shadow evaporation process for wafer-scale fabrication of tunnel junction devices, according to an exemplary embodiment of the disclosure. In particular, FIGS. 2A and 2B schematically illustrate an exemplary double-angle shadow evaporation process which utilizes the shadow evaporation mask 100 for wafer-scale fabrication of overlapping metallic electrodes of tunnel junction devices, wherein FIG. 2A schematically illustrates a configuration of a double-angle shadow evaporation process 200 for wafer-scale fabrication of tunnel junction devices, and FIG. 2B schematically illustrates an exemplary tunnel junction device that can be fabricated using the double-angle shadow evaporation process, according to an exemplary embodiment of the disclosure. In addition, FIG. 2C is a schematic cross-sectional view of an exemplary overlap area of the tunnel junction device of FIG. 2B along line 2C-2C in FIG. 2B.

As schematically illustrated in FIG. 2A, the exemplary double-angle shadow evaporation process 200 is configured for wafer-scale fabrication of tunnel junction devices over a given wafer 210 (e.g., silicon wafer) comprising a plurality of chips 220. In an exemplary embodiment, the chips 220 comprises quantum chips which comprise quantum bits and other quantum components that are constructed using superconducting tunnel junction devices (e.g., Josephson junctions). For purposes of explaining an exemplary configuration of the double-angle shadow evaporation process 200, FIG. 2A illustrates a three-dimensional cartesian coordinate system which comprises an X-axis (alternatively referred to herein as parallel axis), a Y-axis (alternatively referred to herein as perpendicular axis), and a Z-axis, and which has an origin that corresponds to a center point of the wafer 210. In this regard, the surface of the wafer 210 defines an X-Y plane at Z=0. The X-axis (or parallel axis) comprises a first central longitudinal axis which extends (in the X-Y plane) through the center point of the wafer 210, and the Y-axis (or perpendicular axis) comprises a second central longitudinal axis which extends (in the X-Y plane) through the center point of the wafer 210, wherein the second central longitudinal axis (e.g., Y-axis) is perpendicular to the first central longitudinal axis (e.g., X-axis).

As further schematically illustrated in FIG. 2A, the exemplary double-angle shadow evaporation process 200 comprises (i) a first evaporation process E1 that is performed by directing evaporated metallic material at the wafer 210 through a given shadow evaporation mask, wherein the evaporated metallic material is emitted from an evaporation (point) source 230-1 at a first deposition angle, and (ii) a second evaporation process E2 that is performed by directing evaporated metallic material at the wafer 210 through the given shadow evaporation mask, wherein the evaporated metallic material is emitted from an evaporation (point) source 230-2 at a second deposition angle. In some embodiments, the exemplary double-angle shadow evaporation process 200 is configured such that the first and second evaporation processes E1 and E2 are performed with the respective evaporation (point) sources 230-1 and 230-2 disposed in the X-Z plane (y coordinate=0), and disposed at the same vertical height (e.g., z coordinate) above the reference plane (e.g., X-Y plane of surface of the wafer 210 or stage on which the wafer 210 is mounted).

FIG. 2B schematically illustrates an exemplary tunnel junction device that is fabricated using the double-angle shadow evaporation process 200 of FIG. 2A in conjunction with the exemplary shadow evaporation mask 100 of FIGS. 1A-1C, wherein it is assumed that the patterned opening 103 is disposed in a central region of the wafer 210 near the origin of the X-Y-Z coordinate system shown in FIG. 2B, and that the edges e3 and e4 of the patterned opening 103 are aligned in the y-direction. In the illustrative embodiments, the first evaporation process E1 results in the formation of a first metal electrode 231, which comprises a shadow image of the patterned opening 103. After the first evaporation process E1, an oxide layer 232 is formed on the exposed surfaces of the first metal electrode 231, wherein the oxide layer 232 serves as the tunnel barrier layer of the tunnel junction device. Next, the second evaporation process E2 results in the formation of a second metal electrode 233, which comprises a shadow image of the patterned opening 103, but which is laterally offset from the first metal electrode 231, thereby forming an overlap region 234 which defines the area of the tunnel junction device.

As schematically illustrated in FIG. 2B, the overlap region 234 comprises a parallelogram-shaped area (with non-right angles) which is defined by a given amount of overlap of the first and second metal electrodes 231 and 233 in the x-direction, denoted X_{O}, and a given amount of overlap of the first and second metal electrodes 231 and 233 in the y-direction, denoted Y_{O}. As shown in FIG. 2C, the parallelogram-shaped overlap region 234 of the first and second metal electrodes 231 and 233, with a portion of the oxide layer 232 disposed therebetween, defines the area of the tunnel junction device.

As schematically illustrated in FIG. 2A, during the electron-beam evaporation processes E1 and E2, the evaporation (point) sources 230-1 and 230-2 generate respective diverging metal flows that have conical shapes. In this regard, when the deposition angles of the first and second evaporation processes E1 and E2 are set relative to the center region (e.g., origin) of the wafer 210, the actual deposition angles will vary over the area of the wafer 210 from the center point of the wafer 210 to the edges of the wafer 210. With a conventional shadow evaporation mask design, the variation in the deposition angle over the area of wafer 210 would cause different shadow sizes of the patterned openings of the shadow evaporation mask, resulting in nanoscale misalignment of junction electrode positions over the wafer and changes in the linear dimensions of the junction electrodes, and thus leading to variation in the sizes (areas) of tunnel junction devices in different chips 220 disposed in different regions of the wafer 210.

In contrast, the exemplary shadow evaporation mask designs as disclosed herein are configured to enable double-angle shadow evaporation fabrication of tunnel junction devices (e.g., Josephson junctions) at a wafer scale, where the tunnel junction devices are fabricated with uniform area over the wafer area despite changes in the deposition angles based on the different positions of the tunnel junction devices over the area of the wafer. The exemplary shadow evaporation masks are configured to provide self-correction of the junction area of the tunnel junction devices over a relatively large wafer area such that the junction areas of the tunnel junction devices are invariant over the wafer area, i.e., the junction areas of the tunnel junction devices do not change depending on the position of the tunnel junction devices on the wafer.

The exemplary shadow evaporation masks are configured to compensate for geometric dimensional errors in the x-direction and y-direction such that the amount of overlap of the first and second metal electrodes of the respective tunnel junction devices is the same in both lateral (x and y) directions, i.e., the amount of the X_{O} and Y_{O} overlap of the first and second metal electrodes of the tunnel junction devices is substantially the same, and essentially invariant, over different regions/areas (e.g., chips) wafer, irrespective of the position-dependent changes in the evaporation deposition angles. For example, in the context of the exemplary configuration of the double-angle shadow evaporation process 200 shown in FIG. 2A, a shadow evaporation mask is designed with patterned openings that are configured to compensate for (i) a first component of error due to the perpendicular position of a given tunnel junction device in the y-direction relative to the central (parallel) X axis, and (ii) a second component of error due to the parallel position of a given tunnel junction device in the x-direction relative to the central (perpendicular) Y axis.

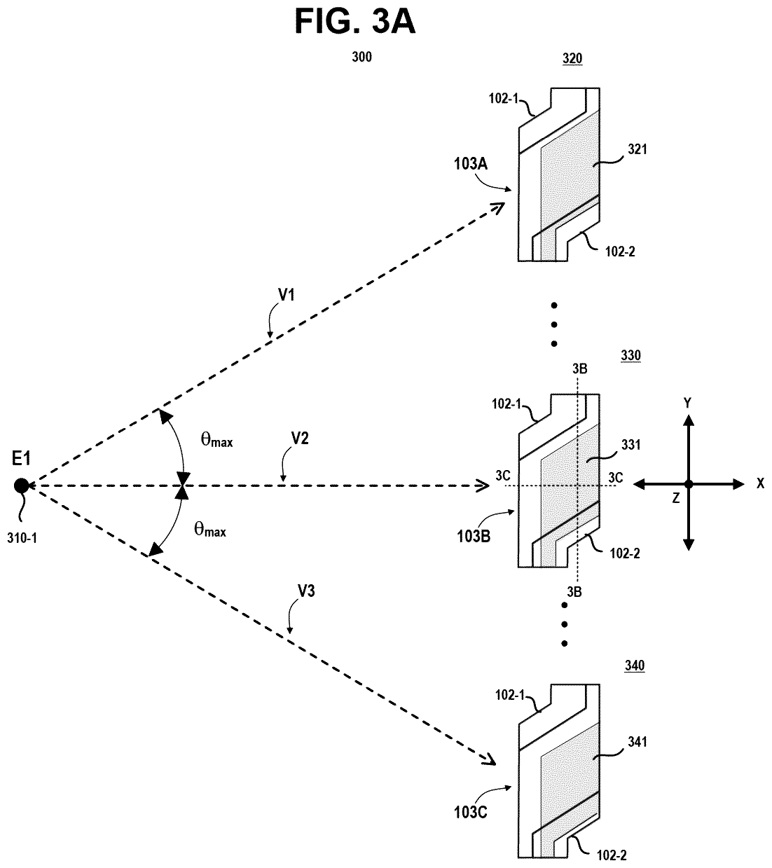

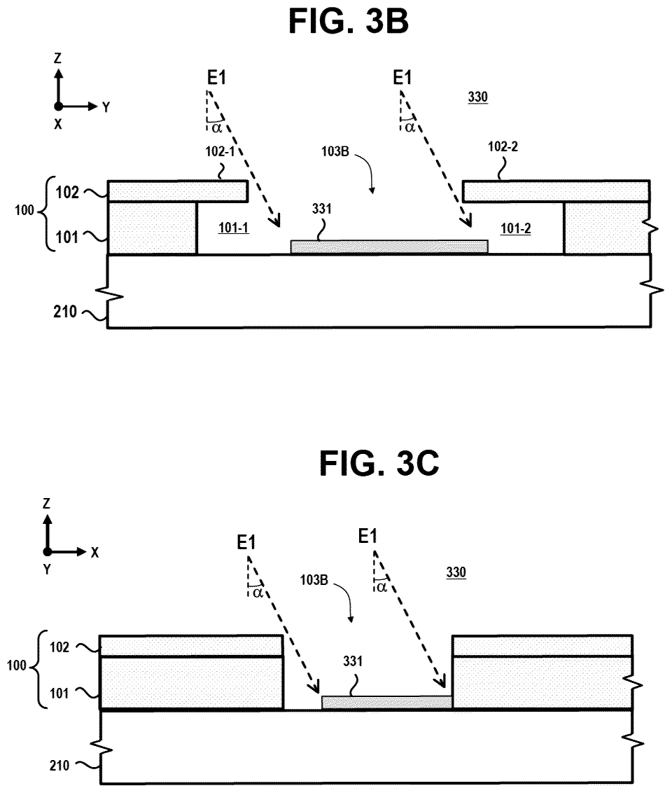

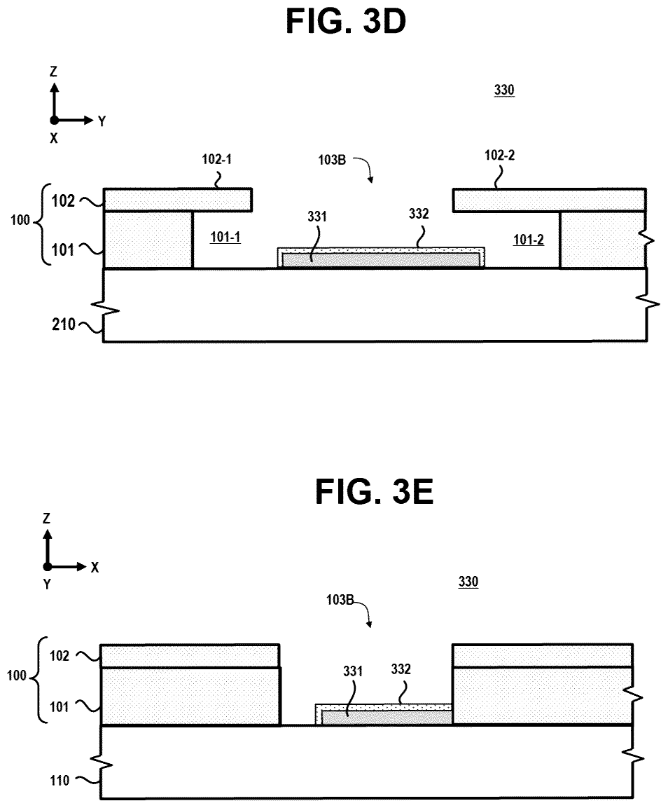

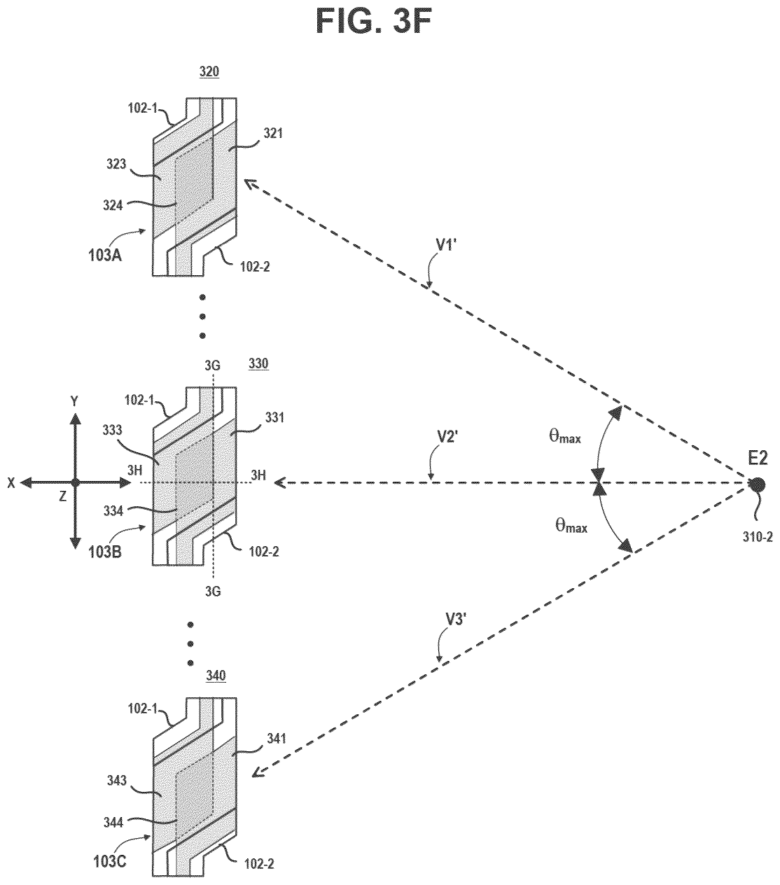

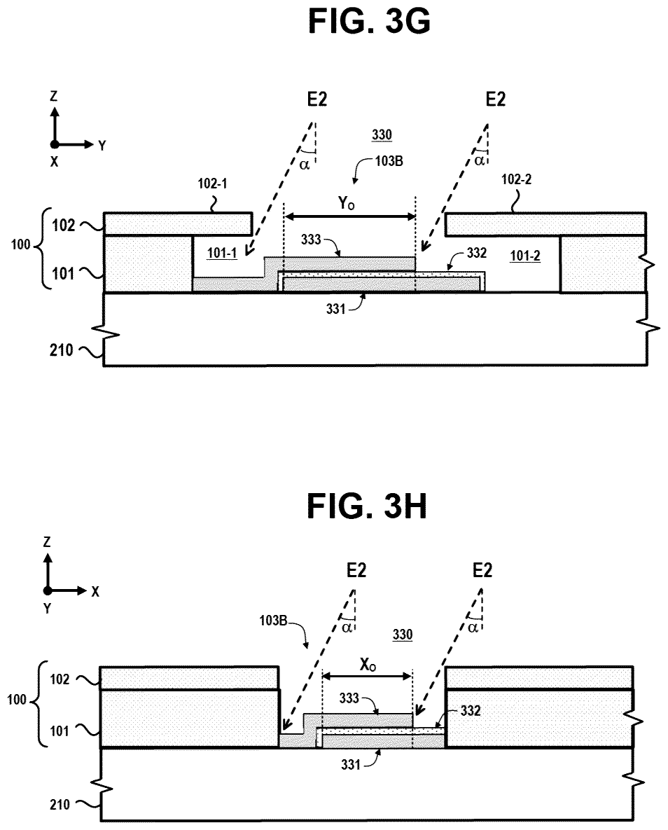

FIGS. 3A, 3B, 3C, 3D, 3E, 3F, 3G, and 3H schematically illustrate a double-angle shadow evaporation process for wafer-scale fabrication of tunnel junction devices, according to an exemplary embodiment of the disclosure. For purposes of illustration, the exemplary double-angle shadow evaporation process 300 will be discussed in the context of the exemplary wafer 210, and the shadow evaporation mask 100, and the exemplary configuration/positioning of evaporation (point) sources 310-1 and 310-2, similar to the configuration/positioning of the evaporation (point) sources 230-1 and 230-2 as shown in FIG. 2A with regard to the first central longitudinal (X) axis (or parallel axis) and the second central longitudinal (Y) axis (or perpendicular axis). Moreover, for purposes of illustration, the exemplary double-angle shadow evaporation process 300 will be discussed in the context of a shadow evaporation mask comprising at least three instances of the patterned opening 103 (shown in FIGS. 1A-1C, and 2B) for evaporation fabrication of three tunnel junction devices 320, 330, and 340.

For example, FIG. 3A schematically illustrates a first evaporation process E1 that is performed by directing evaporated metallic material at the wafer 210 from an evaporation (point) source 310-1 through a given shadow evaporation mask having three patterned openings 103A, 103B, and 103C, each having the same geometric dimensions and configuration based on the patterned opening 103 as discussed above. For purposes of discussion, it is assumed that the patterned openings 103A, 103B, and 103C are aligned in a Y direction along the perpendicular axis (second central longitudinal (Y) axis) of the wafer 210, and that the patterned opening 103B is aligned to the parallel axis (first central longitudinal (X) axis) of the wafer 210. In addition, the patterned opening 103A is assumed to be positioned near an edge of the wafer 210 at a furthest positive Y position on the perpendicular axis from a central point (e.g., origin) of the wafer 210, and the patterned opening 103C is assumed to be positioned near an edge of the wafer 210 at a furthest negative Y position on the perpendicular axis from the central point of the wafer 210. In addition, the evaporation (point) source 310-1 is assumed to be disposed in the X-Z plane at a given height h (positive Z point) above the X-Y plane, and at a linear distance d along the X axis (e.g., negative X point) from the center point (XYZ origin) of the wafer 210.

In some embodiments, the first evaporation process E1 is performed by evaporating a superconducting metal (e.g., aluminum) in a vacuum environment and directing the evaporated superconducting metal at the wafer 210 from the evaporation (point) source 310-1 through the patterned openings 103A, 103B, and 103C to deposit the vaporized metal onto the surface of the wafer 210, where the vaporized metal material then condenses to form the respective first metal electrodes 321, 331, and 341 of the respective tunnel junction devices 320, 330, and 340. As schematically shown in FIG. 3A, given that the evaporation (point) source 310-1 is essentially a point source, the flow of the evaporated metal has a conical shape, which is represented by dashed line vectors V1, V2, and V3, which leads to different evaporation angles in a direction along the perpendicular (Y) axis.

In particular, as schematically shown in FIG. 3A, the dashed line vector V2 represents the flow of evaporated metal that is directed at the patterned opening 103B, where the evaporated metal flows in a direction along the XZ plane such that the dashed line vector V2 has an angle of 0 degrees with respect to the XZ plane. On the other hand, the dashed line vector V1 represents the flow of evaporated metal that is directed at the patterned opening 103A, where the evaporated metal flows in a direction that forms an angle of θₘₐₓ with respect to the XZ plane to reach the patterned opening 103A that is disposed at a positive Y position on the perpendicular Y axis near an edge of the wafer 210. Similarly, the dashed line vector V3 represents the flow of evaporated metal that is directed at the patterned opening 103C, where the evaporated metal flows in a direction that forms an angle of θₘₐₓ with respect to the XZ plane to reach the patterned opening 103C that is disposed at a negative Y position on the perpendicular Y axis near an opposite edge of the wafer 210.

Due to the angular variation, FIG. 3A shows that the shadow images of the first metal electrodes 321, 331, and 341, which are generated by the respective patterned openings 103A, 103B, and 103C as a result of the evaporation process E1, will have similar shapes, but with different offsets relative to the patterned openings 103A, 103B, and 103C. In particular, as schematically shown in FIG. 3A, the positions of the first metal electrodes 321, 331, and 341 progressively shift in a downward direction (negative y direction) such that increasingly more area of the first metal electrodes 321, 331, and 341 are formed under the respective overhang portions 102-2 of the patterned openings 103A, 103B, and 103C. However, the varying offsets of the first metal electrodes 321, 331, and 341 will have no adverse effect on the area uniformity of the resulting tunnel junction devices 320, 330, and 340 in instances where, as noted above, the maximum angles θₘₐₓ do not exceed the angle θ between the central X axis (e.g., parallel axis) of the wafer 210 and each of the first and second angled edges e1 and e2 of the overhang portions 102-1 and 102-2 of the patterned openings 103A, 103B, and 103C.

The first evaporation process E1 in FIG. 3A is further illustrated by FIGS. 3B and 3C, wherein FIG. 3B is a schematic cross-sectional side view along line 3B-3B in FIG. 3A, and FIG. 3C is a schematic cross-sectional side view along line 3C-3C in FIG. 3A. In particular, FIGS. 3B and 3C schematically illustrate an intermediate stage in the fabrication of the tunnel junction device 330 where a shadow image of the first metal electrode 331 is formed on the surface of the wafer 210 as a result of the first evaporation process E1 through the patterned opening 103B of the shadow evaporation mask 100. FIGS. 3B and 3C illustrate dashed line vectors that represent the flow of evaporated metal that is directed at the patterned opening 103B as a result of the evaporation process E1, wherein the evaporation is at an angle α from the Z axis. In some embodiments, the angle α represents the evaporation angle that is selected for the first evaporation process E1, where the angle represents the angle of direct path from the evaporation (point) source 310-1 to the center point (origin) of the wafer 210, where the patterned opening 103B is assumed to be positioned near the center point of the wafer 210. The dashed line vectors which represent the evaporated metal flow that is directed at the patterned opening 103B are assumed to be substantially parallel given the long distance between the evaporation (point) source 310-1 and the patterned opening 103B, relative to the nanometer dimensions of the patterned opening 103B.

Following the first evaporation process E1, an in-situ oxidation process is performed to form oxide layers on the exposed surfaces of the first metal (aluminum) electrodes 321, 331, and 341. For example, in some embodiments, immediately following the first evaporation process E1, oxygen (O₂) is flowed into the evaporation chamber (without breaking the vacuum) to expose the metal electrodes to oxygen at a fixed concentration and pressure for a given time, to oxidize the exposed surfaces of the first metal electrodes 321, 331, and 341, via diffusive oxidation of the surfaces of the metal electrodes, and thereby form thin oxide layers (e.g., aluminum oxide) on the first metal (aluminum) electrodes 321, 331, and 341. The oxide layers serve as tunnel barrier layers of the tunnel junction devices. The desired thickness of the oxide layers will be selected to achieve desired operating characteristics of the tunnel junction devices. For example, for superconducting Josephson junctions, the tunnel barrier thickness is engineered to achieve a desired critical current of the Josephson junction.

The result of the oxidation process is schematically illustrated in FIGS. 3D and 3E, where a thin oxide layer 332 is formed on exposed surfaces of the first metal electrode 331. FIG. 3D is a schematic cross-sectional side view, which corresponds to the schematic cross-sectional side view of FIG. 3B, showing a resulting structure after forming the thin oxide layer 332 (e.g., aluminum oxide layer) on the exposed surfaces of the first metal electrode 331 (e.g., aluminum electrode). Similarly, FIG. 3E is a schematic cross-sectional side view, which corresponds to the schematic cross-sectional side view of FIG. 3C, showing the resulting structure after forming the thin oxide layer 332 (e.g., aluminum oxide layer) on the expose surfaces of the first metal electrode 331 (e.g., aluminum electrode).

Following the oxidation process, a second evaporation process is performed (without breaking the vacuum in the evaporation chamber) to form respective second electrodes of the tunnel junction devices 320, 330, and 340. For example, FIG. 3F schematically illustrates a second evaporation process E2 that is performed by directing evaporated metallic material at the wafer 210 from an evaporation (point) source 310-2 through the shadow evaporation mask of FIG. 3A having the three patterned openings 103A, 103B, and 103C. Similar to FIG. 3A, the patterned openings 103A, 103B, and 103C are aligned in a Y direction along the perpendicular axis (second central longitudinal (Y) axis) of the wafer 210, and the patterned opening 103B is aligned to the parallel axis (first central longitudinal (X) axis) of the wafer 210. In addition, the evaporation (point) source 310-2 is assumed to be disposed in the X-Z plane at a given height above the X-Y plane. In addition, the evaporation (point) source 310-1 is assumed to be disposed in the X-Z plane at a given height h (positive Z point) above the X-Y plane, and at a linear distance d along the X axis from the center point (XYZ origin) of the wafer 210.

In some embodiments, the configuration of the second evaporation process E2 of FIG. 3F is similar to the configuration of the first evaporation process E1 of FIG. 3A, except that the evaporation (point) source 310-2 in FIG. 3F is disposed at a position in the XZ plane which corresponds to the position the evaporation (point) source 310-1 in FIG. 3A with the XZ plane rotated 180 degrees about the Z axis. In this regard, the evaporation sources 310-1 and 310-2 can be the same evaporation source that is just rotated 180 degrees around the Z axis to provide the two separate evaporation angles. In another embodiment, the position of the evaporation (point) source 310-1 in FIG. 3A can remain fixed, while the wafer 210 is rotated 180 degrees and the second evaporation process E2 is performed using the fixed evaporation source.

In some embodiments, the second evaporation process E2 is performed by evaporating a superconducting metal such as aluminum in the vacuum environment and directing the evaporated metal at the wafer 210 from the evaporation (point) source 310-2 through the patterned openings 103A, 103B, and 103C to deposit the vaporized metal material onto the surface of the wafer 210, where the vaporized metal material then condenses to form respective second metal electrodes 323, 333, and 343 of the respective tunnel junction devices 320, 330, and 340. As schematically shown in FIG. 3F, given that the evaporation (point) source 310-2 is essentially a point source, the flow of the evaporated metal has a conical shape, which is represented by dashed line vectors V1′, V2′, and V3′, which leads to different evaporation angles in a direction along the perpendicular (Y) axis.

The dashed line vectors V1′, V2′, and V3′ correspond to the dashed line vectors V1, V2, and V3, respectively, of FIG. 3A. For example, as schematically shown in FIG. 3F, the dashed line vector V2′ represents the flow of evaporated metal that is directed at the patterned opening 103B, where the evaporated metal flows in a direction along the XZ plane such that the dashed line vector V2′ has an angle of 0 degrees with respect to the XZ plane. On the other hand, the dashed line vector V1′ represents the flow of evaporated metal that is directed at the patterned opening 103A, where the evaporated metal flows in a direction that forms an angle of θₘₐₓ with respect to the XZ plane to reach the patterned opening 103A that is disposed at a positive Y position on the perpendicular Y axis near an edge of the wafer 210. Similarly, the dashed line vector V3′ represents the flow of evaporated metal that is directed at the patterned opening 103C, where the evaporated metal flows in a direction that forms an angle of θₘₐₓ with respect to the XZ plane to reach the patterned opening 103C that is disposed at a negative Y position on the perpendicular Y axis near an opposite edge of the wafer 210.

Due to the angular variation, FIG. 3F shows that the shadow images of the second metal electrodes 323, 333, and 343, which are generated by the respective patterned openings 103A, 103B, and 103C as a result of the second evaporation process EE, will have similar shapes, but with different offsets relative to the patterned openings 103A, 103B, and 103C. In particular, as schematically shown in FIG. 3F, the positions of the second metal electrodes 323, 333, and 343 progressively shift in a downward direction (negative y direction) such that increasingly less area of the second metal electrodes 323, 333, and 343 is formed under the respective overhang portions 102-1 of the patterned openings 103A, 103B, and 103C.

However, the varying offsets of the second metal electrodes 323, 333, and 343 have no adverse effect on the area uniformity of the resulting tunnel junction devices 320, 330, and 340 in instances where, as noted above, the maximum angles θₘₐₓ do not exceed the angle θ between the central X axis (e.g., parallel axis) of the wafer 210 and each of the first and second angled edges e1 and e2 of the overhang portions 102-1 and 102-2 of the patterned openings 103A, 103B, and 103C. Indeed, as schematically illustrated in FIG. 3F, the tunnel junction devices 320, 330, and 340 are defined by respective overlap areas 324, 334, and 344 of the associated first and second metal electrodes, wherein the overlap areas 324, 334, and 344 are parallelogram-shaped and have substantially the same dimensions and thus substantially the same footprint area.

The second evaporation process E2 in FIG. 3F is further illustrated by FIGS. 3G and 3H, wherein FIG. 3G is a schematic cross-sectional side view along line 3G-3G in FIG. 3F, and FIG. 3H is a schematic cross-sectional side view along line 3H-3H in FIG. 3F. In particular, FIGS. 3G and 3H schematically illustrate a final stage in the fabrication of the tunnel junction device 330 where a shadow image of the second metal electrode 333 is formed as a result of the second evaporation process E2 through the patterned opening 103B of the shadow evaporation mask 100. FIGS. 3G and 3H illustrate dashed line vectors that represent the flow of evaporated metal that is directed at the patterned opening 103B as a result of the second evaporation process E2, wherein the evaporation is at an angle α from the Z axis. As noted above, in some embodiments, the angle α represents the evaporation angle that is selected for second first evaporation process E2, where the angle represents the angle of direct path from the evaporation (point) source 310-2 to the center point (origin) of the wafer 210, where the patterned opening 103B is assumed to be positioned near the center point of the wafer 210. The dashed line vectors which represent the evaporated metal flow that is directed at the patterned opening 103B are assumed to be substantially parallel given the long distance between the evaporation (point) source 310-2 and the patterned opening 103B, relative to the nanometer dimensions of the patterned opening 103B.

As schematically illustrated in FIGS. 3G and 3H, the second metal electrode 333 overlaps the first metal electrode 331 by an amount Y₀ in the Y-direction, and by an amount X₀ in the X-direction, wherein the X₀ overlap and Y₀ overlap define the overlap area 334 shown in FIG. 3F. The overlap area 334 between the first and second metal electrodes 331 and 333, with a portion of the thin oxide layer 332 disposed therebetween, defines the area of the tunnel junction device 330. With the exemplary process shown in FIGS. 3A-3F, the respective X₀ overlaps and Y₀ overlaps between (i) the first and second metal electrodes 321 and 323 of the tunnel junction device 320, (ii) the first and second metal electrodes 331 and 333 of the tunnel junction device 330, (ii) the first and second metal electrodes 341 and 343 of the tunnel junction device 340, will be the same or substantially the same, resulting in the respective overlap areas 324, 334, and 344 having the same or substantially the same dimensions and footprint area.

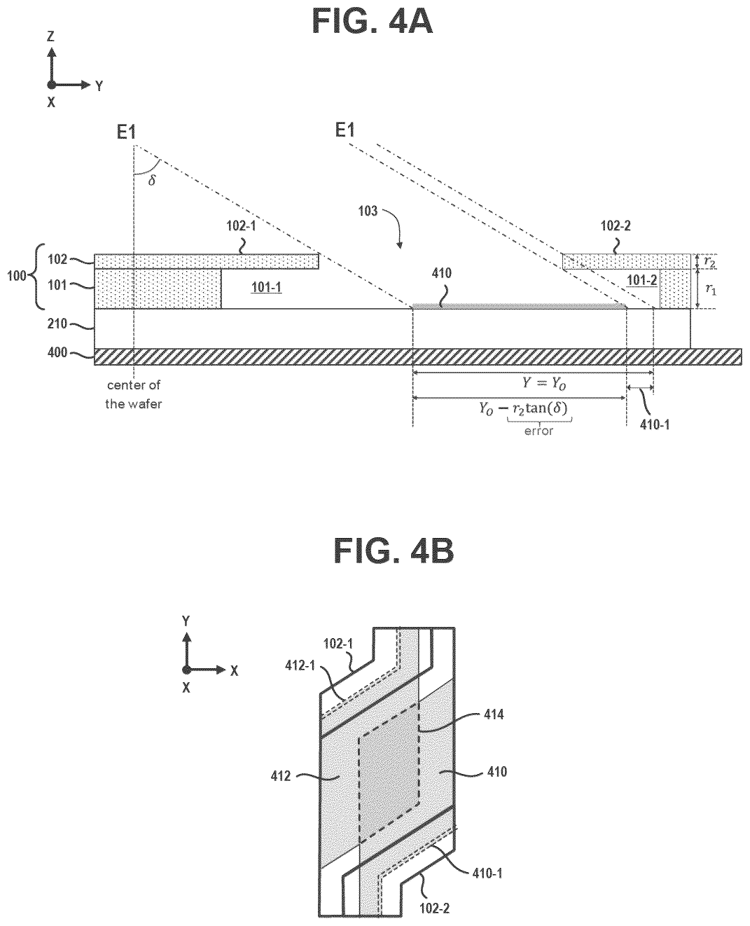

As noted above, the exemplary shadow evaporation mask designs as disclosed herein are configured to enable double-angle shadow evaporation fabrication of tunnel junction devices (e.g., Josephson junctions) at a wafer scale, where the tunnel junction devices are fabricated with uniform area over the wafer area despite changes in the deposition angles based on the different positions of the tunnel junction devices over the area of the wafer. The exemplary shadow evaporation masks are configured to compensate for geometric dimensional errors in the X-direction and Y-direction such that the amount of overlap of the first and second metal electrodes of the respective tunnel junction devices is the same in both lateral (x and y) directions, i.e., the amount of the X_{O} and Y_{O} overlap of the first and second metal electrodes of the tunnel junction devices is substantially the same, and essentially invariant, over different regions/areas (e.g., chips) wafer, irrespective of the position-dependent changes in the evaporation deposition angles. FIGS. 4A, 4B, 5, and 6 illustrate the manners in which the exemplary shadow evaporation mask designs are configured to provide self-correction of the junction area of tunnel junction devices aver a large area of wafer to provide uniform junction area of tunnel junction devices for large scale wafer manufacturing.

For example, FIGS. 4A and 4B illustrate a method by which a shadow evaporation mask is configured to compensate for a first component of error in the fabrication of metal electrodes of tunnel junction devices, according to an exemplary embodiment of the disclosure. In particular, FIG. 4A illustrates how an exemplary shadow evaporation mask is configured to provide a second order correction of error that occurs due to a thickness of the shadow evaporation mask with respect to the perpendicular position along the perpendicular axis (Y-axis). FIG. 4A schematically illustrates the exemplary shadow evaporation mask 100 and patterned opening 103, with the shadow evaporation mask 100 formed on the wafer 210, and the wafer 210 disposed on a stage 400 within an evaporation chamber. In addition, FIG. 4A schematically illustrates a first evaporation process E1 that is performed to deposit a first metal electrode 410 on the surface of the wafer 210, which comprises a shadow image of the patterned opening 103.

FIG. 4A illustrates than a given amount of geometric offset error 410-1 of the first metal electrode 410 in the Y direction due to a variation in the thickness of the shadow evaporation mask (e.g., the thickness r₂ of the second resist layer 102 (e.g., PMMA layer)) will have no adverse effect on the electrode overlap area of the tunnel junction device since, for example, the region of the first metal electrode 410 which comprises the geometric offset error 410-1 would be disposed in the undercut region 101-2 of the first resist layer 101 below the overhang portion 102-2 of the second resist layer 102.

Furthermore, FIG. 4B schematically illustrates that with regard to the shadow evaporation fabrication of a second metal electrode 412, any resulting geometric offset error 412-1 of the second metal electrode 412 in the Y direction due to the variation in the thickness of the shadow evaporation mask 100 would be disposed in the undercut region 101-1 of the first resist layer 101 below the overhang portion 102-1 of the second resist layer 102. As shown in FIG. 4B, the regions of potential geometric offset errors 410-1 and 412-1 are outside an overlap area 414 between the first and second metal electrodes 410 and 412, which shows that there is no error induced on the junction area of the resulting tunnel junction device as a result of the shadow evaporation mask 100, in particular, a variation in the thickness of the shadow evaporation mask 100. Consequently, irrespective of an error in the desired thickness of the shadow evaporation mask 100, the tunnel junction devices that are fabricated over the wafer 210 would have a same Y_{O} overlap between the respective first and second metal electrodes.

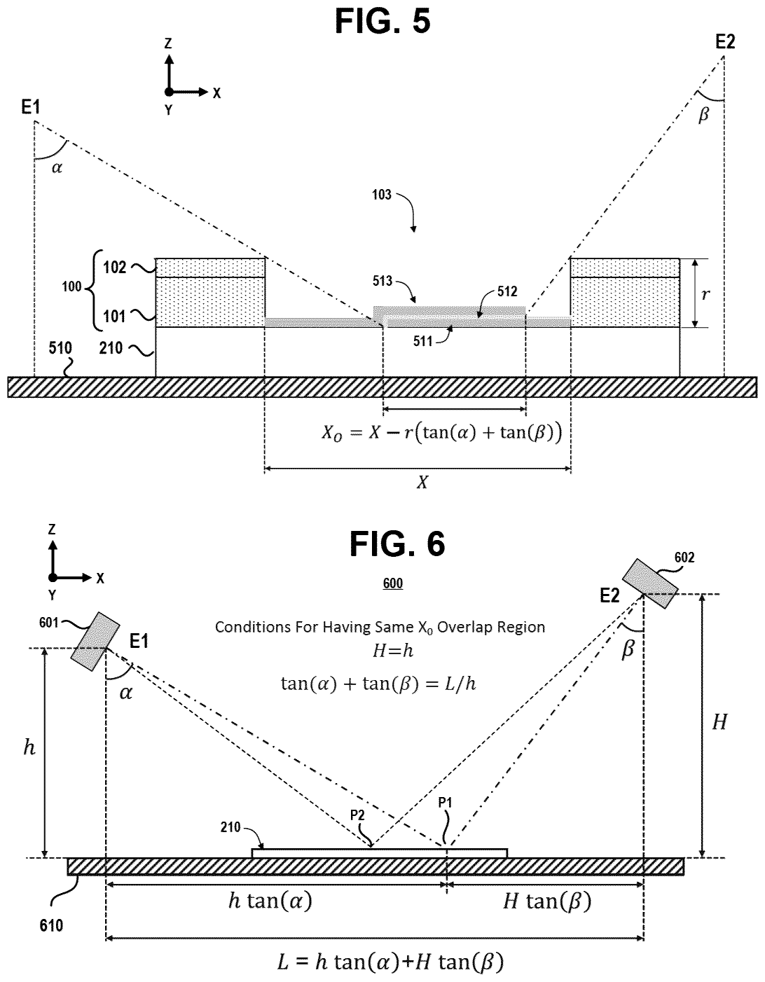

Next, FIGS. 5 and 6 illustrate a method by which a shadow evaporation mask in conjunction with shadow evaporation parameters, is configured to compensate for a second component of error in the fabrication of metal electrodes of tunnel junction devices, according to an exemplary embodiment of the disclosure. In particular, FIG. 5 schematically illustrates a method for determining an amount of lateral overlap of metal electrodes of a tunnel junction device that is fabricated using a double-angle shadow evaporation process, according to an exemplary embodiment of the disclosure. FIG. 6 schematically illustrates exemplary configuration of a double-angle shadow evaporation process for wafer-scale fabrication of tunnel junction devices to achieve a same amount of lateral overlap of metal electrodes of respective tunnel junction devices formed in different areas of the wafer, according to an exemplary embodiment of the disclosure. FIGS. 5 and 6 schematically illustrate how an exemplary shadow evaporation mask and shadow evaporation parameters are configured to correct for errors in X₀ overlap between respective first and second metal electrodes of tunnel junction devices over a wafer to ensure that the tunnel junction devices each have the same or substantially the same X₀ overlap along the parallel axis (X axis) in FIG. 2A, irrespective of deviations in the evaporation angle at different portions over the wafer area.

FIG. 5 schematically illustrates the exemplary shadow evaporation mask 100 and patterned opening 103, with the shadow evaporation mask 100 formed on the wafer 210, and the wafer 210 disposed on a stage 510 within an evaporation chamber. FIG. 5 schematically illustrates a first evaporation process E1 that is performed to deposit a first metal electrode 511 on the surface of the wafer 210, which comprises a shadow image of the patterned opening 103, followed by an in-situ oxidation process to form an oxide layer 512 on exposed surfaces of the first metal electrode 511. In addition, FIG. 5 schematically illustrates second evaporation process E2 that is performed to deposit a second metal electrode 513, which comprises a shadow image of the patterned opening 103.

FIG. 5 further illustrates that in the X-direction, the patterned opening 103 comprises a lateral dimension X, and that a resulting tunnel junction device is formed by an overlapping region having an X₀ overlap between the first and second metal electrodes 511 and 513 with a portion of the oxide layer 512 disposed between the overlapping first and second metal electrodes 511 and 513. The evaporated metal of the first evaporation process E1 is shown to have a first angle of incidence α to the surface of the wafer 210, and the evaporated metal of the second evaporation process E2 is shown to have a second angle of incidence β to the surface of the wafer 210, wherein the first and second angles α and β are different angles, and based on the position of the patterned opening 103 over the area of the wafer 210. Based on the exemplary parameters shown in FIG. 5, the amount of X₀ overlap between the first and second metal electrodes 511 and 513 is determined as: X_{O}=X−r(tan (α)+tan (β)).

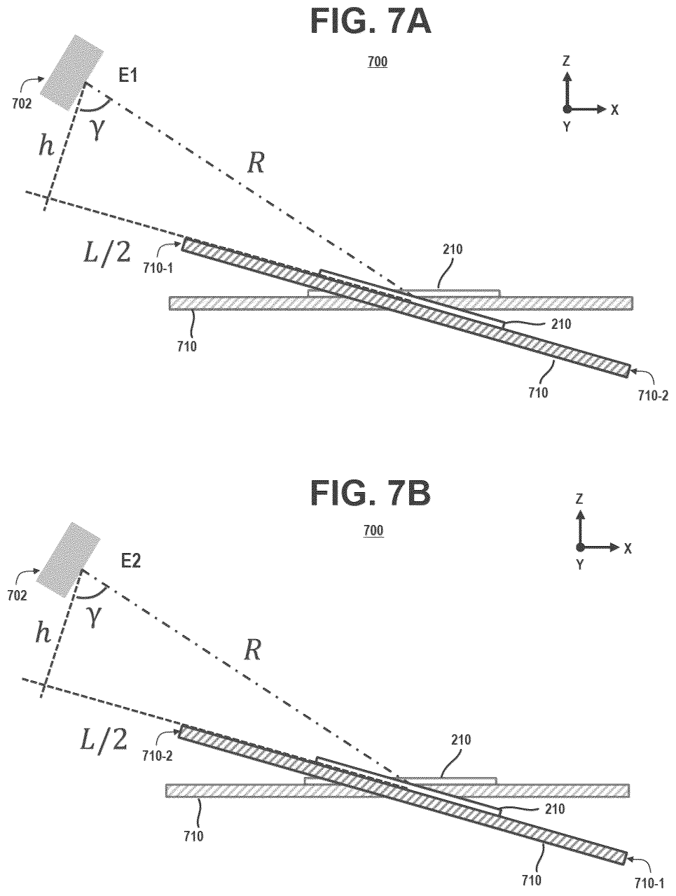

FIG. 6 schematically illustrates exemplary evaporation parameters that are selected to ensure that a wafer scale fabrication of tunnel junction devices results in tunnel junction devices having a same amount of X₀ overlap between respective first and second metal electrodes of the tunnel junction devices irrespective of the position of the tunnel junction devices on the wafer, according to an exemplary embodiment of the disclosure. In particular, FIG. 6 illustrates an exemplary configuration 600 of a double-angle shadow evaporation process to enable wafer-scale fabrication of tunnel junction devices over a wafer 210 that is disposed on a wafer stage 610. FIG. 6 schematically illustrates a first crucible 601 (or first evaporation (point) source) to perform a first evaporation process E1 and a second crucible 602 (or second evaporation (point) source) to perform a second evaporation process E2. As is known in the art, a crucible is a component which includes the material that is to be evaporated (evaporant) and deposited. The evaporant (e.g., superconducting metal material such as aluminum) is heated to vaporization, and the vaporized material is directed at a given angle to the surface of the wafer to form thin film features such as metal electrodes of tunnel junction devices. Although separate first and second crucibles 601 and 602 are shown for purposes of illustration, in some embodiments, the e-beam evaporation system would include a single crucible that is positioned and utilized for both evaporation processes E1 and E2 by moving the crucible or rotating the wafer 210. Furthermore, in some embodiments, the wafer stage 610 is configured for both rotation and tilt, wherein the tilting of the wafer stage 610 allows for changing of the evaporation angle, as will be discussed in further detail below in conjunction with FIGS. 7A and 7B.

FIG. 6 schematically illustrates a first point P1 on the surface of the wafer 210 wherein the evaporated metal of the first evaporation process E1 is shown to have a first angle of incidence α to the surface of the wafer 210, and the evaporated metal of the second evaporation process E2 is shown to have a second angle of incidence β to the surface of the wafer 210, wherein the first and second angles α and β are different angles. In addition, FIG. 6 schematically illustrates a second point P2 on the surface of the wafer 210 wherein the incident angles of the evaporated metal of the respective first and second evaporation processes E1 and E2 at the second point P2 are shown to be different from the incident angles α and β of the evaporated metal of the respective first and second evaporation processes E1 and E2 at the first point P1.

In some embodiments, to ensure that the amount of X₀ overlap between first and second metal electrodes of a first tunnel junction device formed at the first point P1 on the surface of the wafer 210 is the same or substantially similar to the amount of X₀ overlap between first and second metal electrodes of a second tunnel junction device formed at the second point P2 on the surface of the wafer 210, the following evaporation parameters are selected. For example, the height h of the first crucible 601 and the height H of the second crucible 602 are set to the same height, i.e., h=H, above the surface of the wafer stage 610 in the XZ plane. In addition, the first and second crucibles 601 and 602 are disposed in the XZ plane (Y=0) and at a lateral distance L (in the X-direction), and where the first and second crucibles 601 and 602 are disposed at a lateral distance L/2 (in the X-direction) from a center point of the wafer 210.

In this exemplary configuration, a constant overlap region is imposed by setting X_{O}=X−r(tan (α)+tan (β))=constant, where (tan (α)+tan (β))=c. Based on the relationship between the different parameters, the lateral distance L is equal to: L=h tan (α)+H tan (β), which can be restated as: L/h=tan (α)+H/h tan (β). However, with h=H, then L/h=tan (α)+tan (β). With these exemplary conditions, the amount of X₀ overlap between first and second metal electrodes of the tunnel junction devices across the surface of the wafer 210 will be a constant:

$${X}_{O} = X - r ( \frac{L}{h} ) .$$

Next, FIGS. 7A and 7B schematically illustrate a double-angle shadow evaporation process for wafer-scale fabrication of tunnel junction devices, according to another exemplary embodiment of the disclosure. In particular, FIGS. 7A and 7B schematically illustrate an exemplary electron-beam evaporation system 700 which comprises a single evaporation source 702 and a wafer stage 710 that is configured to rotate and tilt. FIG. 7A schematically illustrates an exemplary configuration in which the wafer 210 (with the shadow evaporation mask formed on the surface thereof) is disposed on the wafer stage 710 with a central point (origin) of the wafer 210 disposed at a lateral distance (in X-direction) of L/2. In addition, FIG. 7A shows (i) an evaporation angle γ which represents an angle of the evaporation source 702 to the center point of the wafer 210, (ii) a dashed line R which represents a distance (beam vector) from the evaporation source 702 to the center point of the wafer 210, and (iii) a height h of the evaporation source 702 along normal to a surface of the wafer stage 710.

In the exemplary configuration, the height h is determined as h=R cos (γ), and the parameter L is determined as L=2R sin (γ). To ensure that the amount of X₀ overlap between first and second metal electrodes of tunnel junction devices that are formed across the surface of the wafer 210 will be a constant, the same evaporation angle γ is utilized for first and second evaporation processes E1 and E2 as shown in FIGS. 7A and 7B, so that a constant X₀ overlap of: X_{O}=X−2r tan (γ), where X represent a lateral dimension X of the exemplary patterned opening 103 of the shadow evaporation mask 100, and r denotes a total thickness of the shadow evaporation mask, such as illustrated and discussed above in conjunction with FIGS. 5 and 6.

FIG. 7A schematically illustrates the first evaporation process E1 that is performed by tilting the wafer stage 710 so that the X-Y plane of the wafer stage 710 is set to a height h of a normal line to the X-Y plane of the wafer stage 710, and at the target evaporation angle γ. In FIG. 7A, a first side 710-1 of the wafer stage 710 is tilted up and a second side 710-2 of the wafer stage 710 is tilted down. On the other hand, FIG. 7B schematically illustrates the second evaporation process E2 that is performed by rotating the wafer stage 710 by 180 degrees so that the first side 710-1 of the wafer stage 710 is tilted down away from the evaporation source 720 and the second side 710-2 of the wafer stage 710 is tilted up towards the evaporation source 720. In this exemplary system 700, the evaporation source 702 remains fixed, while the desired evaporation angle γ and height h for the first and second evaporation processes E1 and E2 are configured by rotating and tilting the wafer stage 710 accordingly, while the center point of the wafer 210 remains aligned to the center point of the wafer stage 710.

Although exemplary embodiments have been described herein with reference to the accompanying figures, it is to be understood that the disclosure is not limited to those precise embodiments, and that various other changes and modifications may be made therein by one skilled in the art without departing from the scope of the appended claims.

What is claimed is:

1. A method, comprising:
forming a shadow evaporation mask on a substrate, the shadow evaporation mask comprising a plurality of patterned openings in different regions of the substrate, wherein each of the patterned openings comprises a same size and shaped opening; and
utilizing the shadow evaporation mask to perform a double angle evaporation process to form a plurality of tunnel junction devices in each of the different regions of the substrate, each tunnel junction device comprising a first metal layer and a second metal layer having an overlapping area, wherein the overlapping areas of the tunnel junction devices are invariant over the different regions of the substrate.

2. The method of claim 1, wherein the patterned openings of the shadow evaporation mask are configured to provide self-correction of geometric errors in the forming of the first and second metal layers of the tunnel junction devices in the different regions of the substrate to achieve an invariant amount of overlap area between the first metal layer and the second metal layer of each of the tunnel junction devices over the different regions of the substrate.

3. The method of claim 1, wherein performing the double angle evaporation process comprises:
performing a first evaporation process at a first angle to deposit the first metal layer of each tunnel junction device, wherein the first metal layer of each tunnel junction device comprises a first shadow image of a respective one of the patterned openings;
forming an insulating layer on the first metal layer of each tunnel junction device; and
performing a second evaporation process at a second angle to deposit the second metal layer of each tunnel junction device, wherein the second metal layer of each tunnel junction device comprises a second shadow image of the respective one of the patterned openings.

4. The method of claim 1, wherein the patterned openings of the shadow evaporation mask each comprise a same size and quadrilateral-shaped opening with at least one non-right angle.

5. A method, comprising:
forming a shadow evaporation mask on a substrate, the shadow evaporation mask comprising a plurality of patterned openings in different regions of the substrate, wherein each of the patterned openings comprises a same size and quadrilateral-shaped opening with at least one non-right angle;
performing a first evaporation process at a first angle to deposit first metal layers which comprise first shadow images of the patterned openings;
forming an insulating layer on each of the first metal layers; and
performing a second evaporation process at a second angle to deposit second metal layers which comprise second shadow images of the patterned openings;
wherein portions of the second metal layers overlap respective portions of the first metal layers to form respective tunnel junction devices in the different regions of the substrate, which comprises overlapping regions of metallization having a same size and quadrilateral-shaped footprint with at least one non-right angle.

6. The method of claim 5, wherein the first evaporation process and the second evaporation process are each performed at a same height above the substrate along a central axis of the substrate.

7. The method of claim 5, wherein:
the quadrilateral-shaped opening of each of the patterned openings of the shadow evaporation mask comprises a parallelogram-shaped opening with non-right angles;
each parallelogram-shaped opening comprises a first angled edge and a second angled edge; and
the first angled edge and the second angled edge each comprise an angle relative to a central axis of the substrate, which is larger than a largest evaporation angle of a conical shaped evaporation metal flow generated by an evaporation source when performing the first evaporation process and the second evaporation process.

8. The method of claim 5, wherein:
performing the first evaporation process comprises evaporating and depositing a superconducting metal material to form the first metal layers;
forming an insulating layer on each of the first metal layers comprises oxidizing exposed surfaces of the first metal layers to form metal oxide layers; and
performing the second evaporation process comprises evaporating and depositing the superconducting metal material to form the second metal layers.

9. The method of claim 5, wherein:
the first metal layers each comprise an extended portion which provides a first contact pad for the respective tunnel junction devices; and
the second metal layers each comprise an extended portion which provides a second contact pad for the tunnel junction devices.

10. The method of claim 5, wherein the tunnel junction devices comprise Josephson junction of superconducting quantum bits.

11. The method of claim 5, wherein forming the shadow evaporation mask on the substrate, comprises:
depositing a first resist layer on the substrate;
depositing a second resist layer on the first resist layer;
patterning the first resist layer and the second resist layer to form the patterned openings in the first resist layer and the second resist layer;
wherein the patterned openings of the second resist layer each comprise a first suspended portion and a second suspended portion which comprise a respective first angled edge and a second angled edge of the quadrilateral-shaped opening; and
wherein the patterned openings of the first resist layer each comprise a first undercut region below the first suspended portion, and a second undercut region below the second suspended portion.

12. The method of claim 11, wherein:
the first resist layer comprises a spin-coated methyl methacrylate layer; and
the second resist layer comprises spin-coated poly methyl methacrylate layer.

13. A device comprising a shadow evaporation mask comprising a first layer and a second layer disposed over the first layer, and a plurality of uniformly patterned openings that are configured for fabricating respective uniformly shaped tunnel junction devices on a substrate by double-angle shadow evaporation.

14. The device of claim 13, wherein each patterned opening comprises a quadrilateral-shaped opening with a least one right angle, which is configured to generate shadow images of overlapping electrodes of a respective tunnel junction device.

15. A device, comprising:
a first metal layer disposed on a substrate;
an insulating layer disposed on the first metal layer; and
a second metal layer disposed on the insulating layer;
wherein a portion of the second metal layer overlaps a portion of the first metal layer to form a stacked structure comprising an overlapping area of metallization with a portion of the insulating layer disposed therebetween, wherein the stacked structure comprises a tunnel junction device having a quadrilateral-shaped footprint with a least one non-right angle.

16. The device of claim 15, wherein:
the first metal layer and the second metal layer each comprise a superconducting metal; and
the insulating layer comprises an oxide of the superconducting metal.

17. The device of claim 15, wherein:
the quadrilateral-shaped footprint of the tunnel junction device comprises a parallelogram-shaped footprint with non-right angles; and
the first metal layer and the second metal layer each comprise a parallelogram-shaped area with non-right angles.

18. The device of claim 17, wherein:
the first metal layer comprises an extended portion which provides a first contact pad for the tunnel junction device; and
the second metal layer comprises an extended portion which provides a second contact pad for the tunnel junction device.

19. The device of claim 16, wherein the tunnel junction device comprises a Josephson junction of a superconducting quantum bit.

20. A device, comprising:
a plurality of tunnel junction devices disposed on a substrate;
wherein each tunnel junction device comprises a respective stacked structure which comprises overlapping portions of a first metal layer and a second metal layer, and an insulating layer disposed therebetween; and
wherein the respective stacked structure comprises a quadrilateral-shaped footprint with a least one non-right angle.

21. The device of claim 20, wherein the quadrilateral-shaped footprints of the stacked structures have substantially a same footprint area as.

22. The device of claim 20, wherein:
the first metal layer and the second metal layer each comprise a superconducting metal; and
the insulating layer comprises an oxide of the superconducting metal.

23. The device of claim 20, wherein:
the first metal layer and the second metal layer each comprise a quadrilateral-shaped footprint area with at least one non-right angle; and
the overlapping portions of a first metal layer and a second metal layer form the quadrilateral-shaped footprint of the stacked structure.

24. The device of claim 20, wherein:
the first metal layer comprises an extended portion which provides a first contact pad for the tunnel junction device; and
the second metal layer comprises an extended portion which provides a second contact pad for the tunnel junction device.

25. The device of claim 20, wherein the tunnel junction devices comprise Josephson junctions of superconducting quantum bits.
